(19) United States
(12) Patent Application Publication
(10) Pub. No.: US 2018/0015614 A1
(43) Pub. Date: Jan. 18, 2018

(54) ROBOT SHAKES AUTOMATICALLY ADJUSTING DEVICE AND METHOD OF AUTOMATICALLY ADJUSTING SHAKES OF ROBOT

(71) Applicant: KAWASAKI JUKOGYO KABUSHIKI KAISHA, Kobe-shi, Hyogo (JP)

(72) Inventors: Kazuo FUJIMORI, Kakogawa-shi (JP); Masaya YOSHIDA, Himeji-shi (JP)

(73) Assignee: KAWASAKI JUKOGYO KABUSHIKI KAISHA, Kobe-shi, Hyogo (JP)

(21) Appl. No.: 15/548,953

(22) PCT Filed: Feb. 4, 2015
(86) PCT No.: PCT/JP2015/000501

§ 371 Date: Aug. 4, 2017

(51) Int. Cl. B25J 9/16; B25J 9/12; G05B 19/29; H01L 21/687; B25J 11/00

(52) U.S. Cl. CPC B25J 9/1641; H01L 21/68707; B25J 11/0095; G05B 19/298; B25J 9/12; G05B 2219/34013; Y10S 901/02; Y10S 901/14; Y10S 901/23

(57) ABSTRACT

A robot shakes automatically adjusting device includes a parameter optimizing part configured to newly set any one of a plurality of control parameters to a control parameter setter when a shakes evaluation value is above a given threshold, and optimize a combination of the plurality of control parameters by causing the control parameter setter, a robot control part, a shakes acquiring part, and a determining part to repeat the new setting of the control parameters, a linear movement of an end effector, an acquisition of the shakes, and a determination, respectively, until the shakes evaluation value becomes below the given threshold.

### TECHNICAL FIELD

The present disclosure relates to a robot shakes automatically adjusting device and a method of automatically adjusting shakes of a robot.

### BACKGROUND ART

Generally, when conveying in a semiconductor processing facility, semiconductor wafers, glass substrates for display panels, etc., a horizontal link-type articulated conveyance robot is used. In the link-type conveyance robot, shakes in lateral directions (hereinafter; referred to as “lateral shakes”) occur with respect to an operating route of the robot during a straight-line operation.

In the link-type conveyance robot, operation of a hand is determined by several kinds of parameters for controlling the operation of each joint shaft. Thus, a measuring instrument is conventionally used, and manually, all the parameters of a straight line operation pattern are adjusted manually to adjust the lateral shakes of the robot.

### DESCRIPTION OF THE DISCLOSURE

### Problems to be Solved by the Disclosure

However, the conventional method requires know-how and skills for adjustments and measurements of measuring instruments, working hours varies depending on the worker's capability, and accuracy may be less. Such a problem is common to robots in general which performs the straight line operation. Furthermore, such a problem is common not only to the lateral shakes but also other shakes of the robots in general, such as longitudinal shakes and oblique shakes.

Therefore, the purpose of the present disclosure is to automatically and easily adjust shakes of a robot.

### SUMMARY OF THE DISCLOSURE

A robot shakes automatically adjusting device according to one aspect of this disclosure is a device configured to automatically adjust shakes when a given part of a tip-end part of an arm of a robot moves linearly, the arm having a plurality of joint shafts. The device includes a memory part configured to store beforehand a target route on which the given part moves linearly, and a plurality of control parameters for controlling operation of each of the shafts of the arm so that the given part moves linearly following the target route, a control parameter setter configured to set values of the plurality of control parameters, a robot control part configured to control the operation of each of the shafts of the arm based on the target route and the set plurality of control parameters so that the given part moves linearly, a shakes acquiring part configured to acquire, as the shakes, a deviation of a route of the given part with respect to the target route, between points on the target route and points on the route when the given part moves linearly at one or more timings, respectively, during the linear movement, a determining part configured to determine whether a shakes evaluation value that is one of a value of the shakes and a weighted value of the shakes acquired by the shakes acquiring part is below a given threshold, and a parameter optimizing part configured to newly set any one of the plurality of control parameters to the control parameter setter when the shakes evaluation value is above the given threshold, and optimize a combination of the plurality of control parameters by causing the control parameter setter, the robot control part, the shakes acquiring part, and the determining part to repeat the new setting of the control parameters, the linear movement of the given part, the acquisition of the shakes, and the determination, respectively, until the shakes evaluation value becomes below the given threshold.

Here, the term “shakes” refers to the deviation of a position of the given part with respect to the target route on which the given part moves linearly. That is, the shakes includes shakes of at least one direction of a lateral direction, a longitudinal direction, and an oblique direction with respect to the target route.

According to the configuration, since the shakes of the given part moving linearly (e.g., end effector) are able to be converged within a given range by repeatedly changing the plurality of control parameters comprehensively, the optimal combination of the control parameters is determined. As a result, the control parameters of the given part of the robot are automatically adjustable without depending on the conventional manual labor.

The arm may include servomotors configured to drive the plurality of joint shafts, respectively. The parameter optimizing part may change preferentially the control parameters related to a speed and an angular velocity of a rotor of a servomotor of each of the shafts.

According to the configuration, since the control parameters largely contributing to the shakes of the linear movement route are preferentially changed, it can suitably converge the shakes.

The determining part may determine, after the shakes evaluation value becomes below the given threshold, whether the shakes evaluation value acquired by the shakes acquiring part is below a second threshold that is smaller than the given threshold. The parameter optimizing part may newly set any one of the plurality of control parameters to the control parameter part when the shakes evaluation value is above the second threshold, and optimize the combination of the plurality of control parameters by causing the control parameter setter, the robot control part, the shakes acquiring part, and the determining part to repeat the new setting of the control parameters, the linear movement of the given part, the acquisition of the shakes, and the determination, respectively, until the shakes evaluation value becomes below the second threshold.

According to the configuration, since the threshold is divided into multiple stages and the threshold is made gradually smaller, it is easy to be converged on a more stably solution.

The deviation of the route of the given part may be acquired based on a measurement jig provided with a surface parallel to the target route of the given part, and a range sensor provided to the given part and configured to measure a distance of the given part with respect to the measurement jig.

According to the configuration, the deviation of an operating route can suitably be measured.

The robot may be a horizontal articulated robot. The given part may be an end effector attached to the tip end of the arm of the robot. The shakes acquiring part may acquire, as lateral shakes, a deviation of the route of the end effector in lateral directions perpendicular to the target route with respect to the target route, between points on the target route and points on the route when the end effector moves linearly, at one or more timings, respectively, during the linear movement of the end effector.

A method of automatically adjusting robot shakes according to another aspect of this disclosure is a method being executed by a shakes automatically adjusting device which automatically adjusts shakes when a given part of a tip-end part of an arm of a robot moves linearly, the arm having a plurality of joint shafts. The method includes storing beforehand in a memory part, a target route on which the given part moves linearly, and a plurality of control parameters for controlling operation of each of the shafts of the arm so that the given part moves linearly following the target route, setting values of the plurality of control parameters, controlling the operation of each of the shafts of the arm based on the target route and the set plurality of control parameters so that the given part moves linearly, acquiring, as the shakes, a deviation of a route of the given part with respect to the target route, between points on the target route and points on the route when the given part moves linearly at one or more timings, respectively, during the linear movement, determining whether a shakes evaluation value that is one of a value of the shakes and a weighted value of the shakes that are acquired is below a given threshold, and newly setting any one of the plurality of control parameters when the shakes evaluation value is above the given threshold, and optimizing a combination of the plurality of control parameters by repeating the new setting of the control parameters, the linear movement of the given part, the acquisition of the shakes, and the determination, until the shakes evaluation value becomes below the given threshold.

The given part may be an end effector attached at the tip end of the atm of the robot. The acquiring the shakes may include acquiring, as lateral shakes, a deviation of the route of the end effector in lateral directions perpendicular to the target route with respect to the target route, between points on the target route and points on the route when the end effector moves linearly at one or more timings, respectively, during the linear movement of the end effector.

### Effect of the Disclosure

According to the present disclosure, shakes of the robot is automatically and easily adjustable.

The purpose described above, other purposes, features and advantages of the present disclosure will be made clear from the following detailed description of a suitable embodiment with reference to the accompanying drawings.

### BRIEF DESCRIPTION OF DRAWINGS

FIG. 1 is a schematic view illustrating a configuration of a shakes automatically adjusting system of a robot according to one embodiment.

FIG. 2 is a block diagram illustrating a configuration of a control device of the robot of FIG. 1.

FIG. 3 is a block diagram illustrating one example of part of the configuration of the control device of FIG. 2.

FIG. 4 is a flowchart illustrating one example of lateral shakes automatic adjustment processing of the robot.

FIG. 5 is a graph illustrating one example of a measurement result of lateral shakes.

### MODE FOR CARRYING OUT THE DISCLOSURE

Hereinafter, one embodiment according to the present disclosure is described with reference to the accompanying drawings. Below, the same reference numerals are assigned to the same or corresponding components throughout the drawings and, thus redundant description is omitted.

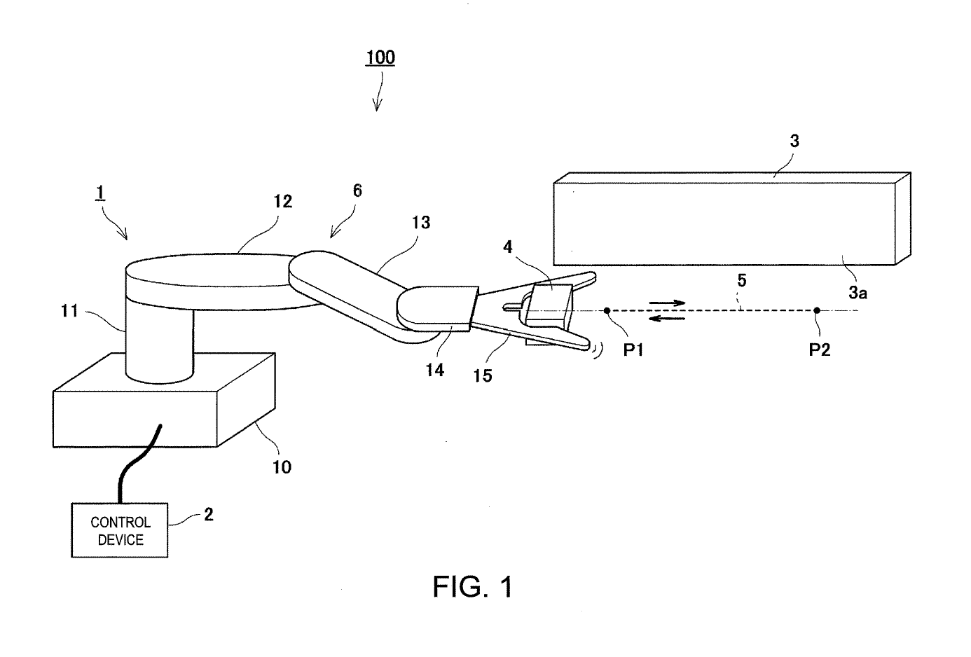

FIG. 1 is a schematic view illustrating a configuration of a shakes automatically adjusting system of a robot according to one embodiment. As illustrated in FIG. 1, a robot shakes automatically adjusting system 100 (shakes automatically adjusting device) includes a control device 2, a measurement jig 3, and a range sensor 4. Reference numeral 1 is a robot which is a target of shakes adjustment. Note that, below, although “lateral shakes” of the robot 1 is illustrated as “shakes” of the robot 1, “shakes” of the robot 1 is suitably adjustable similar to the following illustration.

For example, the robot 1 includes an arm 6 having a plurality of joint shafts, and an end effector 15 provided to a tip-end part of the arm 6. The robot 1 is not limited in particular as long as the robot includes the arm having a plurality of joint shafts. Here, the term “joint shaft” as used herein refers to a so-called “joint,” which includes a rotary joint which performs a rotational movement, and a straight-movement joint which performs a straight movement. Thus, the robot 1 includes linear-motion robot, other than a so-called “articulated robot.” In this embodiment, the robot is a horizontal articulated robot for conveyance. The robot 1 conveys, for example, semiconductor wafers in a semiconductor processing facility, glass substrates for display panels, etc. Here, the arm 6 of the robot 1 is comprised of an elevatable shaft 11 provided onto a base 10, a first link 12 provided to the elevatable shaft 11, a second link 13 provided to a tip-end part of the first link 12, a third link 14 provided to a tip-end part of the second link 13, and the end effectors 15 provided to a tip-end of the third link 14. A servomotor for drive, an encoder which is one example of an angle detector detectable of an angle of a joint, etc. (none of them is illustrated) are incorporated into each joint shaft (not illustrated) of the arm 6. The end effector 15 is, for example, a hand. Although the hand grips a substrate (not illustrated), such as a semiconductor wafer, when conveying the substrate, it grips herein the range sensor 4 for measurement instead.

The control device 2 controls operation of each shaft of the arm 6 so that the end effector 15 moves linearly following a target route 5 on which the end effector 15 carries out a linear movement. The target route 5 of the end effector 15 is a straight line illustrated by a dotted line connecting a point P1 and a point P2, and is comprised of an outward way from the point P1 to the point P2, and a return way from the point P2 to the point P1. That is, by extending and contracting the arm 6, the end effector 15 moves linearly on the outward way from the starting point P1 (standby position) to the point P2 (instructed position), then moves linearly on the return way from the point P2 to the point P1 to return to the original standby position. Although FIG. 1 illustrates only one target route 5, the target route is set to each of a plurality of ports of where position and height are different, such as FOUP, at the time of conveyance.

The measurement jig 3 is disposed along the target route 5 of the end effector 15, and includes a wall surface 3a parallel to the target route 5.

The range sensor 4 is disposed at the end effector 15 and gripped by the end effector 15. In this embodiment, the range sensor 4 includes components, such as a sensor head and a sensor amplifier. Infrared light is emitted onto the wall surface 3a of the measurement jig 3 from the sensor head, and a distance between the range sensor 4 and the wall surface 3a of the measurement jig 3 is measured. By performing this measurement during operation of the robot 1, lateral shakes are measured. The term “lateral shakes” as used herein refers to a deviation (deflection) with respect to the target route 5 of a route of the end effector 15 in the lateral directions perpendicular to the target route 5, between the point on the target route 5 and the point on the route when the end effector 15 moves linearly, respectively, at one or more timings during the linear movement. That is, although the shakes includes shakes of at least one direction of the lateral direction, the longitudinal direction, and the oblique direction with respect to the target route 5, the shakes in the lateral direction perpendicular to the target route 5 is measured in this embodiment.

The range sensor 4 is configured to output measurement results to the control device 2 by wireless or wired communications.

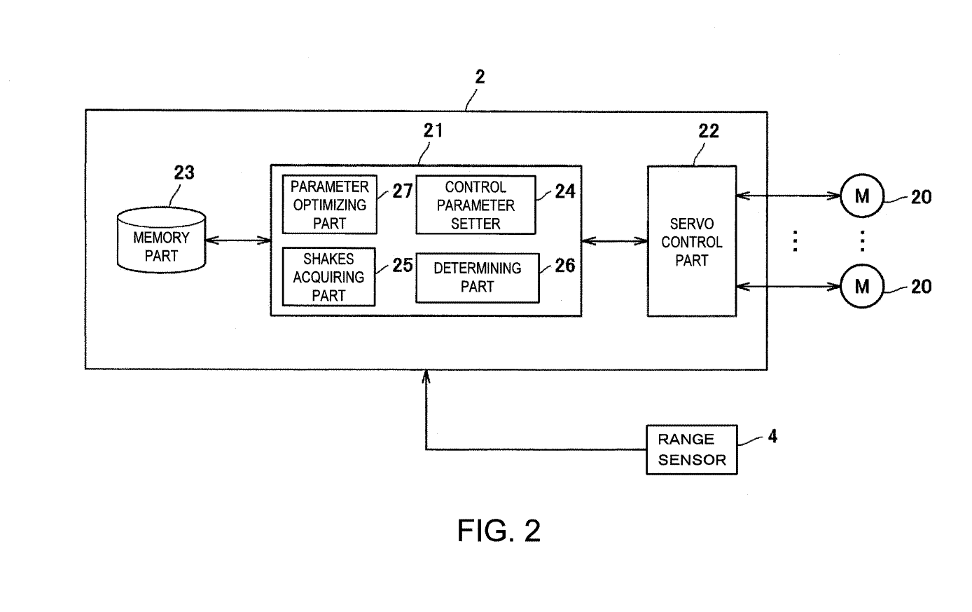

FIG. 2 is a block diagram illustrating a configuration of the control device 2. As illustrated in FIG. 2, the control device 2 includes an operation part 21, a servo control part 22, a memory part 23, and a communication interface (not illustrated). The control device 2 is connected with the robot 1 through a control line (not illustrated), and for example, is a robot controller including a computer, such as a micro controller. In this embodiment, the control device 2 has a function to automatically adjust the lateral shakes of the robot 1. The control device 2 is not limited to a single device but may be comprised of a plurality of devices including a device which has an automatic adjustment function of shakes described later. Here, it is configured so that the arm 6 is driven by the servomotors 20 while a positional control of the plurality of servomotors 20 built in each joint shaft of the arm 6 is performed.

The memory part 23 stores beforehand a basic program of the control device 2, an operation program of the robot, the target route 5, and control parameters.

The operation part 21 is an arithmetic unit which executes various kinds of operation processings for the robot control. The operation part 21 executes the basic program of the control device 2, the operation program of the robot, and the shakes automatic adjustment program to generate a robot control instruction and output it to the servo control part 22. Moreover, the operation part 21 is configured to achieve each functional block including a control parameter setter 24, a shakes acquiring part 25, a determining part 26, and a parameter optimizing part 27 (each operates as a functional block).

The control parameter setter 24 sets values of a plurality of control parameters, respectively. Here, the control parameters are a plurality of adjustment parameters for controlling operation of each shaft of the arm 6 so that the end effector 15 moves linearly following the target route 5. Note that the control parameters may be any kind of parameters as long as they are adjustment parameters which influence the “shakes” of the robot 1.

The servo control part 22 controls operation of each shaft of the arm 6 so that the end effector 15 moves linearly based on the target route 5, and the plurality of control parameters which are set.

The shakes acquiring part 25 acquires a shakes evaluation value which is a value of shakes or a weighted value of the shakes. Specifically, the shakes acquiring part 25 receives the measurement data related to the shakes from the range sensor 4, and then calculates the shakes evaluation value based on the measurement data.

The determining part 26 determines whether the shakes evaluation value which is the value of the shakes or the weighted value of the shakes acquired by the shakes acquiring part 25 is below a given threshold.

If the shakes evaluation value is above the given threshold, the parameter optimizing part 27 causes the control parameter setter 24 to newly set any one of the plurality of control parameters, and until the shakes evaluation value becomes below the given threshold, causes the control parameter setter 24, the servo control part 22, the shakes acquiring part 25, and the determining part 26 to repeatedly perform the new setting of the control parameters, the linear movement of the end effector 15, the acquisition of shakes, and the determination, respectively, to optimize the combination of the plurality of control parameters.

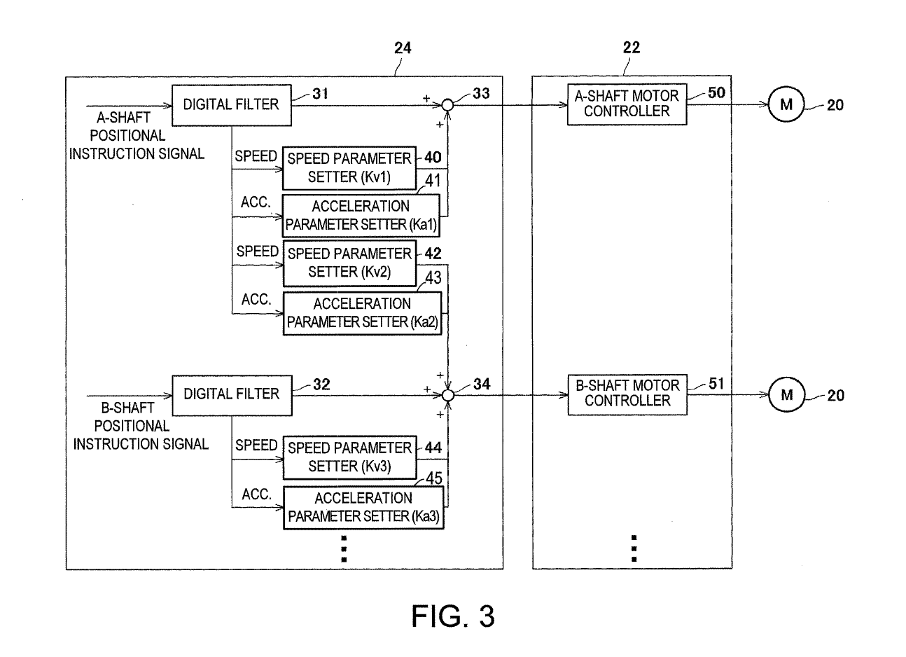

FIG. 3 is a block diagram illustrating one example of part of configurations of the control parameter setter 24 and the servo control part 22 in the control device 2. In FIG. 3, although only a motor control of the joint shaft of the third link 14 (hereinafter, referred to as “A-shaft”) and the joint shaft of the end effector (hand) 15 (hereinafter, referred to as “B-shaft”) of FIG. 1 is illustrated, since the same can be said for other joint shafts, the description thereof is omitted.

As illustrated in FIG. 3, the control parameter setter 24 includes digital filters 31 and 32, adders 33 and 34, parameter setters 40-45 for speed and acceleration, and motor controllers 50 and 51 for the A-shaft and the B-shaft. Here, the speed and acceleration are a speed and an angular velocity of rotors of the servomotors 20 of the A-shaft and the B-shaft. The control parameters are, for example, a speed feedforward gain Kv1 of the A-shaft, an acceleration feedforward gain Ka1 of the A-shaft, and a speed feedforward gain Kv2 for causing operation of the A-shaft to act on the B-shaft, and an acceleration feedforward gain Ka2 for causing operation of the A-shaft act on the B-shaft, a speed feedforward gain Kv3 of the B-shaft, and an acceleration feedforward gain Ka3 of the B-shaft.

The digital filter 31 filters an A-shaft positional instruction signal inputted from the operation part 21, and then outputs it to the adder 33, the speed parameter setter 40, the acceleration parameter setter 41, the speed parameter setter 42, and the acceleration parameter setter 43. The digital filter 31 is, for example, a FIR filter.

The speed parameter setter 40 weights the speed feedforward gain Kv1 to the filtered A-shaft positional instruction signal inputted from the digital filter 31, and then outputs it to the adder 33. The acceleration parameter setter 41 weights the acceleration feedforward gain Ka1 to the filtered A-shaft positional instruction signal inputted from the digital filter 31, and then outputs it to the adder 33.

The adder 33 adds up respective operation results inputted from the digital filter 31, the speed parameter setter 40, and the acceleration parameter setter 41, and then outputs it to the motor controller 50. Thus, it is configured so that, before the positional control of the A-shaft, a feedforward compensation is carried out by carrying out the control parameter addition of the speed and acceleration to the A-shaft positional instruction signal.

The motor controller 50 carries out a feedback control of the operations of the servomotors 20 of the A-shaft based on the A-shaft positional instruction after the feedforward compensation which is inputted from the adder 33.

The speed parameter setter 42 weights the speed feedforward gain Kv2 to the A-shaft positional instruction signal inputted from the digital filter 31, and then outputs it to the adder 34.

The acceleration parameter setter 43 weights the acceleration feedforward gain Ka2 to the A-shaft positional instruction signal inputted from the digital filter 31, and then outputs it to the adder 34.

The digital filter 32 filters a B-shaft positional instruction signal inputted from the operation part 21, and then outputs it to the adder 34, the speed parameter setter 44, and the acceleration parameter setter 45. The digital filter 32 is, for example, a FIR filter.

The speed parameter setter 44 weights the speed feedforward gain Kv3 to the filtered B-shaft positional instruction signal inputted from the digital filter 32, and then outputs it to the adder 34.

The acceleration parameter setter 45 weights the acceleration feedforward gain Ka3 to the filtered B-shaft positional instruction signal inputted from the digital filter 32, and then outputs it to the adder 34.

The adder 34 adds up respective operation results inputted from the speed parameter setter 42, the acceleration parameter setter 43, the digital filter 32, the speed parameter setter 44, and the acceleration parameter setter 45, and then outputs them to the motor controller 51 of the B-shaft. Thus, it is configured so that, before the positional control of the B-shaft, a feedforward compensation is performed by adding the control parameters of the speed and acceleration related to the A-shaft, and the control parameters of the speed and acceleration related to the B-shaft to the B-shaft positional instruction signal.

The motor controller 51 carries out a feedback control of the operations of the servomotors 20 of the B-shaft based on the B-shaft positional instruction after the feedforward compensation, which is inputted from the adder 34.

In this embodiment, it is configured so that, after the feedforward compensation is applied by the control parameter setter 24, the servo control part 22 performs a normal positional control to control the servomotor 20 of each shaft.

Then, in the control parameter setter 24 illustrated in FIG. 3, the operation of the third link 14 is given as the feedforward control to the positional instruction of operation of the hand by setting the values of the control parameters. That is, the angle and position of each shaft of the arm 6 are mutually changeable while maintaining the target route 5 (FIG. 1) of the end effector 15 by setting the values of the control parameters to suitable values for the positional instruction signal of each shaft.

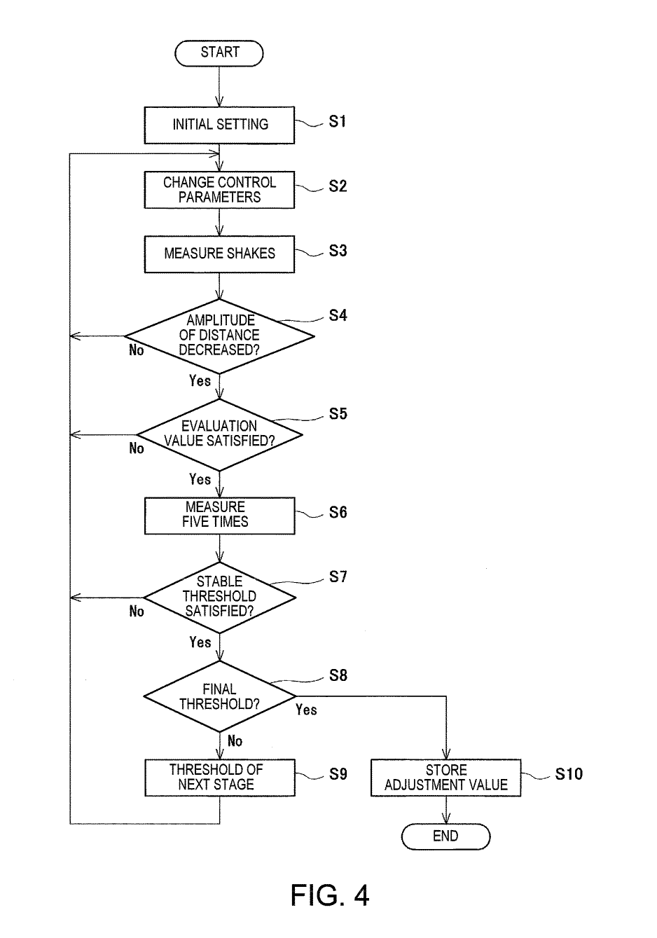

In this embodiment, by utilizing such a configuration, the lateral shakes at the time of linear movement of the end effector 15 are automatically adjusted. Below, the lateral shakes automatic adjustment processing of the robot 1 performed by the control device 2 is described using a flowchart of FIG. 4.

First, initial setting is performed (Step S1). Specifically, zeroing of the range sensor 4 and an offset of the distance between the range sensor 4 and the measurement jig 3 are adjusted. Since a measuring range of the range sensor 4 is determined beforehand by specification, positions of both the range sensor 4 and the measurement jig 3 are corrected so that they enter into the measuring range before the measurement.

Next, the control parameters are changed (Step S2). The control parameter setter 24 sets or changes the values of the plurality of control parameters, respectively. Values determined beforehand are set as initial values at first. Note that in the control parameter setting, the control parameters related to the speed and the angular velocity of the rotor of the servomotor 20 of each shaft illustrated in FIG. 3 are changed preferentially. Since these control parameters largely contribute to the lateral shakes of the linear movement route, they can suitably converge the lateral shakes.

Next, the lateral shakes are measured (Step S3). The servo control part 22 controls operation of each shaft of the arm 6 based on the target route 5 and the set plurality of control parameters at Step S2 so that the end effector 15 moves linearly. By carrying out the extending and contracting operation of the arm 6, the end effector 15 moves linearly on the outward way from P1 to the point P2, and then moves linearly on the return way from the point P2 to the point P1 to return to the original standby position (see FIG. 1). During this operation, the lateral shakes are measured by the range sensor 4, and the shakes acquiring part 25 receives measurement data related to the lateral shakes from the range sensor 4.

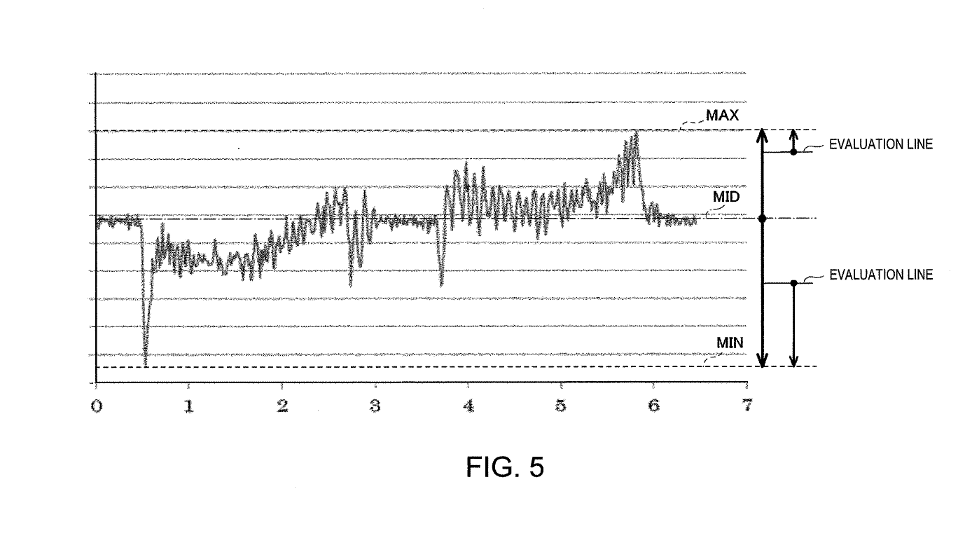

FIG. 5 is a graph illustrating one example of the measurement result of the lateral shakes. In this graph, the horizontal axis indicates time, and the vertical axis indicates the distance between the measurement jig 3 and the range sensor 4. Note that, although an offset of a center value of the measurements is caused due to attachment errors of the range sensor 4 and/or the measurement jig 3, the measurements illustrated here are corrected by digital processing. Here, “MAX” is a maximum value in the plus direction with respect to a center value MID. “MIN” is a minimum value in the minus direction with respect to the center value MID.

As illustrated in FIG. 5, the lateral shakes include lateral shakes in the plus direction and lateral shakes in the minus direction from the center value MID (one-dot chain line) on the target route 5. The term “lateral shakes” as used herein refers to a deviation of a route of the end effector 15 in the lateral directions perpendicular to the target route 5 with respect to the target route 5, between the point on the target route 5 and the point on the route when the end effector 15 moves linearly, respectively, at one or more timings during the linear movement of the end effector 15.

Next, it is determined whether amplitude of the distance is decreased (Step S4). The determining part 26 determines using the lateral shakes evaluation value which is the value of the lateral shakes or the weighted value of the lateral shakes. Thus, in this embodiment, the shakes acquiring part 25 calculates the lateral shakes evaluation value which is the weighted value of the lateral shakes. The formula of the lateral shakes evaluation value is arbitrary. The formula may be such that the evaluation value decreases and becomes below the threshold as the measurement of the lateral shakes approaches to the center. Here, as illustrated in FIG. 5, evaluation lines are set, the lateral shakes evaluation value is weighted less as it is less than the evaluation line in the plus direction, or it is greater than the evaluation line in the minus direction.

Then, the determining part 26 determines whether the lateral shakes evaluation value is below the given threshold.

The parameter optimizing part 27 transits to the following step S5, if the evaluation value is decreased from the evaluation value at the time of a previous measurement. On the other hand, if the evaluation value is the same as or increased from the previous value, the parameter optimizing part 27 returns to Step S2.

Next, it is determined whether the evaluation value satisfies a momentary threshold (Step S5). In this embodiment, the determination is performed using the momentary threshold and a stable threshold. For example, in a first stage, a momentary threshold a1 and a stable threshold b1 are used, and the stable threshold b1 is set as a larger value than the momentary threshold a1. The determining part 26 determines whether the evaluation value satisfies the momentary threshold. If satisfied, the parameter optimizing part 27 transits to the following step, and if not satisfied, it returns to Step S2.

The parameter optimizing part 27 further performs the measurements of the lateral shakes five times (Step S6). Then, the determining part 26 determines whether the evaluation values by these measurements satisfy the stable threshold (Step S7). Thus, it first determines with the momentary threshold which has a smaller value, and only if it is satisfied, the determination is made with the larger stable threshold to eliminate the influences of noise. The parameter optimizing part 27 transits to the following step if the evaluation value satisfies the stable threshold, and if not satisfied, it returns to Step S2.

Next, the parameter optimizing part 27 determines whether the stable threshold used at Step S7 is a final threshold (a stable threshold of a final stage) (Step S8). If the stable threshold is not the final threshold, the parameter optimizing part 27 sets a threshold of a next stage (Step S9), and it returns to Step S2. In this embodiment, three stages of the moment thresholds and stable thresholds are set. In the first stage, the momentary threshold a1 and the stable threshold b1 are set, in the second stage, a momentary threshold a2 and a stable threshold b2 are set, and in the second stage, a momentary threshold a3 and a stable threshold b3 are set. In the third stage, it is set as b3. Each threshold satisfies the following relational expression (1).

a1<b1,a2<b2,a3<b3,a1>a2>a3,b1>b2>b3 (1)

From the relational expression (1), the momentary threshold and the stable threshold are set so as to decrease as the stage goes up. Thus, since the threshold is divided into the multiple stages and the threshold is made gradually smaller, it is easy to be converged on a more stably solution.

Then, if the evaluation value is the final threshold, the parameter optimizing part 27 stores the control parameters and ends (Step S10). As described above, the parameter optimizing part 27 optimizes the combination of the plurality of control parameters by repeating the new setting of the control parameters, the linear movement of the end effector 15, the measurement (acquisition) of the lateral shakes, and the determination, respectively until the lateral shakes evaluation value becomes below the final threshold.

According to this embodiment, since the lateral shakes of the end effector 15 are able to be converged within the given range by repeatedly changing the plurality of control parameters comprehensively, the optimal combination of the control parameters is determined. As a result, the control parameters of the end effector 15 of the robot 1 are automatically adjustable without depending on the conventional manual labor.

Note that, although in this embodiment the case where the lateral shakes are automatically adjusted for one target route 5 (FIG. 1) is illustrated, the target route 5 may be set to each of a plurality of ports where the position and the height are different, and the automatic adjustment processing of the lateral shakes may be performed for every port. For example, if the target route 5 is set for each port of all 24 ports, 1 to 24 ports may be adjusted sequentially with the threshold of the first stage (the momentary threshold and the stable threshold), 1 to 24 ports may then be adjusted sequentially with the threshold of the second stage, and 1 to 24 ports may be adjusted sequentially with the threshold of the final third stage. The influences of noise are removable and it is easy to converge on the optimal solution, rather than the case where the robot 1 performs the adjustment by repeating the same operation for the same port. Moreover, at each stage, the influences of noise is effectively removable by first determining with the momentary threshold which is a smaller value and, only if it is satisfied, then determining with the larger stable threshold.

Note that, in this embodiment, although the lateral shakes of the end effector 15 is measured by the measurement jig 3 provided with the surface 5a parallel to the target route 5 of the end effector 15, and the range sensor 4, it is not limited to this configuration. For example, shakes in at least one direction of the lateral direction, the longitudinal direction, and the oblique direction with respect to the target route 5 may be measured by other acceleration sensors and GPS.

Note that, in this embodiment, although it is configured so that, after applying the feedforward compensation by the control parameter setter 24, the servo control part 22 performs the normal positional control to control the servomotor 20 of each shaft, and the control parameters are the feedforward gains of the speed and the angular velocity of each shaft, the control parameters are not limited to these as long as they influence the shakes of the robot 1.

Note that, in this embodiment, although the robot 1 is the horizontal articulated robot for conveyance, it is not limited to this configuration as long as a robot in general which is capable of moving straight. For example, a robot having a linear motion mechanism may be used. This is because that shakes in all directions may occur in such a robot with respect to the target route on which the robot moves linearly. Moreover, the target route may not be limited to be on the two-dimensional plane but may be any route in a three-dimensional space, and may not be a straight line but may be a curved line.

It is apparent to a person skilled in the art that many improvements and other embodiments of the present disclosure are possible. Therefore, the above description is to be interpreted only as illustration, and it is provided in order to teach a person skilled in the art the best mode which implements the present disclosure. Details of one or both of the structures and the functions may substantially be changed without departing from the spirit of the present disclosure.

### INDUSTRIAL APPLICABILITY

The present disclosure is useful for robots in general which is capable of moving straight.

### DESCRIPTION OF REFERENCE NUMERALS

1: Robot
2: Shakes Automatically Adjusting Device (Control Device)
3: Measurement Jig
4: Range Sensor
5: Target Route
10: Base
11: Elevatable Shaft
12: First Link
13: Second Link
14: Third Link
15: End Effector (Hand)
20: Servomotor
21: Operation Part
22: Servo Control Part
22: Memory Part
23: Control Parameter Setter
25: Shakes Acquiring Part
26: Determining Part
27: Parameter Optimizing Part
31, 32: Digital Filter
33, 34: Adder
40: Speed Parameter Setter (A-shaft)
41: Acceleration Parameter Setter (A-shaft)
42: Speed Parameter Setter (A-shaft to B-shaft)
43: Acceleration Parameter Setter (A-shaft to B-shaft)
44: Speed Parameter Setter (A-shaft)
45: Acceleration Parameter Setter (A-shaft)
50: Motor Controller (A-shaft)
51: Motor Controller (B-shaft)
100: Shakes Automatically Adjusting System

1. A device configured to automatically adjust shakes when a given part of a tip-end part of an arm of a robot moves, the arm having a plurality of joint shafts, the device comprising:
a memory part configured to store beforehand a target route and a plurality of control parameters for controlling operation of each of the shafts of the arm so that the given part moves following the target route;
a control parameter setter configured to set values of the plurality of control parameters;
a robot control part configured to control the operation of each of the shafts of the arm based on the target route and the set plurality of control parameters so that the given part moves;
a shakes acquiring part configured to acquire, as the shakes, a deviation of a route of the given part with respect to the target route, between points on the target route and points on the route when the given part moves at one or more timings, respectively, during the movement;
a determining part configured to determine whether a shakes evaluation value that is one of a value of the shakes, as the deviation, and a weighted value of the shakes acquired by the shakes acquiring part is below a given threshold; and
a parameter optimizing part configured to newly set any one of the plurality of control parameters to the control parameter setter when the shakes evaluation value is above the given threshold, and optimize a combination of the plurality of control parameters by causing the control parameter setter, the robot control part, the shakes acquiring part, and the determining part to repeat the new setting of the control parameters, the movement of the given part, the acquisition of the shakes, and the determination, respectively, until the shakes evaluation value becomes below the given threshold.

2. The shakes automatically adjusting device of claim 1, wherein, the arm includes servomotors configured to drive the plurality of joint shafts, respectively, and
the parameter optimizing part changes preferentially the control parameters related to a speed and an angular velocity of a rotor of a servomotor of each of the shafts.

3. The shakes automatically adjusting device of claim 1, wherein,
the determining part determines, after the shakes evaluation value becomes below the given threshold, whether the shakes evaluation value acquired by the shakes acquiring part is below a second threshold that is smaller than the given threshold, and
the parameter optimizing part newly sets any one of the plurality of control parameters to the control parameter setter when the shakes evaluation value is above the second threshold, and optimizes the combination of the plurality of control parameters by causing the control parameter setter, the robot control part, the shakes acquiring part, and the determining part to repeat the new setting of the control parameters, the movement of the given part, the acquisition of the shakes, and the determination, respectively, until the shakes evaluation value becomes below the second threshold.

4. The shakes automatically adjusting device of claim 1, wherein the deviation of the route of the given part is acquired based on measurement data from a range sensor provided to the given part and configured to measure a distance of the given part with respect to a measurement jig provided with a surface parallel to the target route of the given part.

5. The shakes automatically adjusting device of claim 1, wherein the robot is a horizontal articulated robot.

6. The shakes automatically adjusting device of claim 1, wherein,
the given part is an end effector attached to the tip end of the arm of the robot, and
the shakes acquiring part acquires, as lateral shakes, a deviation of the route of the end effector in lateral directions perpendicular to the target route with respect to the target route, between points on the target route and points on the route when the end effector moves at one or more timings, respectively, during the movement of the end effector.

7. A method being executed by a shakes automatically adjusting device which automatically adjusts shakes when a given part of a tip-end part of an arm of a robot moves, the arm having a plurality of joint shafts, the method comprising:
storing beforehand in a memory part, a target route and a plurality of control parameters for controlling operation of each of the shafts of the arm so that the given part moves following the target route;
setting values of the plurality of control parameters;
controlling the operation of each of the shafts of the arm based on the target route and the set plurality of control parameters so that the given part moves;
acquiring, as the shakes, a deviation of a route of the given part with respect to the target route, between points on the target route and points on the route when the given part moves at one or more timings, respectively, during the movement;
determining whether a shakes evaluation value that is one of a value of the shakes, as the deviation, and a weighted value of the shakes acquired is below a given threshold; and
newly setting any one of the plurality of control parameters when the shakes evaluation value is above the given threshold, and optimizing a combination of the plurality of control parameters by repeating the new setting of the control parameters, the movement of the given part, the acquisition of the shakes, and the determination, until the shakes evaluation value becomes below the given threshold.

8. The method of claim 7, wherein,
the given part is an end effector attached at the tip end of the arm of the robot, and
the acquiring the shakes includes acquiring, as lateral shakes, a deviation of the route of the end effector in lateral directions perpendicular to the target route with respect to the target route, between points on the target route and points on the route when the end effector moves at one or more timings, respectively, during the movement of the end effector.
